(19) United States
(12) Patent Application Publication
(10) Pub. No.: US 2026/0293611 A1
(43) Pub. Date: Sep. 24, 2026

(54) TEMPERATURE-CONTROLLED PEDESTAL FOR SEMICONDUCTOR WAFER PROCESSING

(71) Applicant: Lam Research Corporation, Fremont, CA (US)

(72) Inventors: Jingbin Feng, Ridgefield, WA (US); Bradley Taylor Streng, Tigard, OR (US); Norman M Bourdon, West Linn, OR (US); Aaron Durbin, Portland, OR (US)

(21) Appl. No.: 19/469,273

(22) PCT Filed: Mar. 27, 2024
(86) PCT No.: PCT/US2024/021794

§ 371 Date: Sep. 25, 2025

Related U.S. Application Data
(60) Provisional application No. 63/493,685, filed on Mar. 31, 2023.

(51) Int. Cl. H10P 72/76; H10P 72/00

(52) U.S. Cl. CPC H10P 72/7624; H10P 72/0602

(57) ABSTRACT

Pedestals for supporting semiconductor wafers during wafer processing operations are disclosed. Such pedestals may incorporate both active cooling and active heating systems, thereby allowing them to heat and/or cool wafers through a large range of potential temperatures and to do so rapidly, thereby increasing processing throughput by reducing the wait times needed to allow pedestals to reach a target temperature.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor manufacturing processes often occur within a chamber in which a semiconductor wafer or semiconductor wafers are supported on pedestals during wafer processing operations. Such a pedestal may be positioned underneath a corresponding gas distribution system, e.g., a showerhead, that may be used to distribute process gases across the exposed side of a semiconductor wafer supported by the pedestal.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a pedestal configured to support a semiconductor wafer during semiconductor processing operations. The pedestal may include a main body having a first side and a second side opposite the first side of the main body, one or more heating element segments disposed within the main body and within a first cylindrical region, one or more cooling passage segments disposed within the main body within a second cylindrical region, and a stem connected with the second side of the main body. The first cylindrical region may be interposed between the second cylindrical region and the first side of the main body, and the second cylindrical region may be interposed between the first cylindrical region and the second side of the main body.

In some implementations, the one or more heating element segments may be a plurality of heating element segments, and the plurality of heating element segments may include a plurality of arcuate heating element segments.

In some such implementations, the arcuate heating element segments may be concentric with one another.

In some implementations, the plurality of arcuate heating element segments may include a first heating element segment extending along a first arcuate heating path, a second heating element segment extending along a second arcuate heating path, and a third heating element segment extending along a third arcuate heating path. In such implementations, the first arcuate heating path may have a radius less than a radius of the second arcuate heating path and less than a radius of the third arcuate heating path.

In some such implementations, the first arcuate heating path, the second arcuate heating path, and the third arcuate heating path may be concentric with one another.

In some implementations, the radius of the second arcuate heating path may be equal to the radius of the third arcuate heating path.

In some implementations, the plurality of heating element segments may further include a fourth heating element segment extending along a fourth arcuate heating path and a fifth heating element segment extending along a fifth arcuate heating path, and the radius of the second arcuate heating path and the radius of the third arcuate heating path may be less than a radius of the fourth arcuate heating path and a radius of the fifth arcuate heating path.

In some implementations, the first arcuate heating path, the fourth arcuate heating path, and the fifth arcuate heating path may be concentric with one another.

In some implementations, the radius of the fourth arcuate heating path may be equal to the radius of the fifth arcuate heating path.

In some implementations, the first arcuate heating path, the second arcuate heating path, the third arcuate heating path, the fourth arcuate heating path, and the fifth arcuate heating path may collectively define, at least in part, a plurality of arcuate heating paths, and the plurality of heating element segments may further include a plurality of bridging heating element segments, each bridging heating element segment extending between respective endpoints of a pair of adjacent arcuate heating paths in the plurality of arcuate heating paths.

In some implementations, the one or more cooling passage segments may be a plurality of cooling passage segments, and the plurality of cooling passage segments may include a plurality of arcuate cooling passage segments.

In some implementations, the arcuate cooling passage segments may be concentric with one another.

In some implementations, the plurality of arcuate cooling passage segments may include a first cooling passage segment extending along a first arcuate cooling path and a second cooling passage segment extending along a second arcuate cooling path, the first arcuate cooling path and the second arcuate cooling path may be concentric with one another, and the first arcuate cooling path may have a radius less than a radius of the second arcuate cooling path.

In some such implementations, the first arcuate cooling path and the second arcuate cooling path may be concentric with one another.

In some implementations, the plurality of arcuate cooling passage segments may further include a third cooling passage segment extending along a third arcuate cooling path, the first arcuate cooling path and the third arcuate cooling path may be concentric with one another, and the radius of the second arcuate cooling path may be less than a radius of the third arcuate cooling path.

In some such implementations, the first arcuate cooling path and the third arcuate cooling path may be concentric with one another.

In some implementations, the first arcuate cooling path, the second arcuate cooling path, and the third arcuate cooling path may collectively define, at least in part, a plurality of arcuate cooling paths, and the plurality of cooling passage segments may further include a plurality of bridging cooling passage segments, each bridging cooling passage segment extending between endpoints of two of the arcuate cooling paths in the plurality of arcuate cooling paths.

In some implementations, the main body may include a first portion having a first side and a second side, a second portion having a first side and a second side, and a third portion having a first side and a second side. In such implementations, the second portion may be interposed between the first portion and the third portion, the first side of the first portion may also be the first side of the main body, the second side of the first portion may be bonded to or fused to the first side of the second portion, and the second side of the second portion may be bonded to or fused to the first side of the third portion.

In some implementations, at least one of the second side of the first portion and the first side of the second portion may include a heating element channel, and the heating element channel may house the one or more heating element segments.

In some implementations, the one or more heating element segments may have a D-shaped cross-section.

In some implementations, at least one of the second side of the second portion and the first side of the third portion may include a cooling passage channel, and the cooling passage channel may house the one or more cooling passage segments.

In some implementations, the one or more cooling passage segments may be tubular.

In some implementations, the one or more cooling passage segments may have an annular cross-section.

In some implementations, the second side of the first portion may be brazed to the first side of the second portion, and the second side of the second portion may be brazed to the first side of the third portion.

In some implementations, the first portion, the second portion, and the third portion may all be made of an aluminum alloy.

In some implementations, the main body may be made of an aluminum alloy.

In some implementations, the apparatus may further include a thermocouple coupled with the main body.

In some implementations, the apparatus may further include a power supply, a coolant reservoir having a temperature control system, a coolant pump, and a controller configured to: control the temperature control system to cause a coolant stored in the coolant reservoir to be maintained within a first temperature range that is between 5° C. and 50° C. below a setpoint temperature, control the coolant pump to cause the coolant to flow from the coolant reservoir and through the one or more cooling passage segments, and cause the one or more heating element segments to receive power from the power supply until the temperature sensor indicates that a temperature of the pedestal is at or greater than the setpoint temperature.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a side section view of a pedestal having both active heating and active cooling features.

FIG. 2 depicts a perspective cutaway view of the pedestal of FIG. 1.

FIG. 3 depicts a perspective view of the active heating and active cooling features, as well as a thermocouple element, of the pedestal of FIG. 1.

FIGS. 4A and 4B depict top and bottom views of a first portion of the main body of the pedestal of FIG. 1.

FIGS. 5A and 5B depict top and bottom views of a second portion of the main body of the pedestal of FIG. 1.

FIGS. 6A and 6B depict top and bottom views of a third portion of the main body of the pedestal of FIG. 1.

FIGS. 7 and 8 depict isometric exploded views of the pedestal of FIG. 1.

FIGS. 9 and 10 depict schematics of a semiconductor processing tool having a pedestal such as the pedestal of FIG. 1.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As discussed above, semiconductor wafer processing operations are often performed on semiconductor wafers while such wafers are supported within a processing chamber on a pedestal, e.g., a structure typically designed to support a semiconductor wafer from below in an evenly distributed manner. Disclosed herein are certain pedestals for use in supporting semiconductor wafers during wafer processing operations. Such pedestals may be equipped with both active heating and active cooling elements to allow such pedestals to be rapidly brought to elevated temperatures from cooler temperatures or vice-versa.

For example, pedestals according to the present disclosure may generally have a main body that is typically cylindrical in shape and has a diameter that is larger than the diameter of the semiconductor wafers that the pedestal is designed to support, e.g., larger than 300 mm or 450 mm. The main body may have a first side that is configured to face upwards, e.g., towards a semiconductor wafer supported by the pedestal, during processing operations and a second side that is configured to face downwards, e.g., away from the semiconductor wafer, during processing operations.

Such pedestals may include one or more heating element segments that are disposed within the main body and within a first cylindrical region and one or more cooling passage segments that are disposed within the main body and within a second cylindrical region. The first and second cylindrical regions may be positioned in between the first and second sides of the main body, with the first cylindrical region being interposed between the first side and the second cylindrical region, and the second cylindrical region being interposed between the second side and the first cylindrical region.

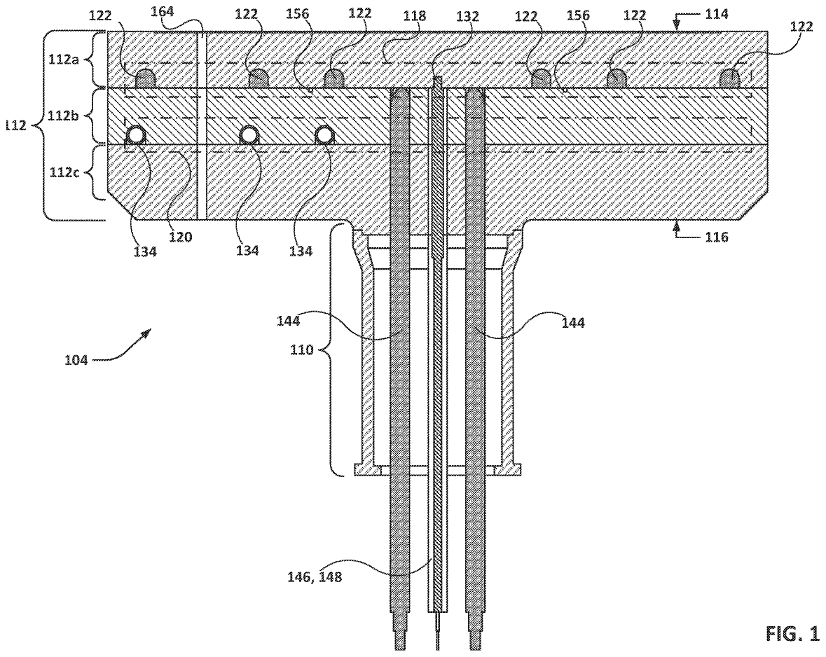

FIG. 1 depicts a cross-sectional view of an example of such a pedestal. In FIG. 1, a pedestal 104 is depicted. The pedestal 104 may include a main body 112 that has a first side 114 and a second side 116. A stem 110 may be connected with the second side 116 of the main body 112, e.g., via a threaded connection, a flange with screws or other threaded fastener connecting the main body 112 to the stem 110, or via a welded or brazed joint. In the depicted example, the stem 110 is brazed to the main body 112. The stem 110 may protrude through an aperture in the floor of the chamber (not shown) housing the pedestal and may be connected with a vertical lift system that is configured to move the stem 110, and the main body 112, up and down in preparation for, or during the performance of, different wafer processing operations.

In the depicted implementation of FIG. 1, the main body 112 is divided into three portions—a first portion 112a, a second portion 112b, and a third portion 112c. These portions 112a, 112b, and 112c may be connected with one another to form a layered structure that forms the main body 112. The layered construction of the main body 112 allows for one or more heating element segments 122 to be placed between the first portion 112a and the second portion 112b and for one or more cooling passage segments 134 to be placed between the second portion 112b and the third portion 112c. As can be seen, the one or more heating element segments 122 are positioned within a first cylindrical region 118, while the one or more cooling passage segments 134 are positioned within a second cylindrical region 120. The first cylindrical region 118, as can be seen, is located between the second cylindrical region 120 and the first side 114 of the main body 112, while the second cylindrical region 120 is located between the first cylindrical region 118 and the second side 116. The first and second cylindrical regions 118 and 120 may share a common center axis and may generally be co-axial with a center axis of the pedestal 104 that is nominally perpendicular to the first side 114. In some implementations, the first cylindrical region 118 may have an upper end that is coincident with the first side 114 and a bottom end that is closer to the first side 114 than any portion of the cooling passage segments 134, while the second cylindrical region 120 may have a lower end that is coincident with the second side 116 of the main body 112 and an upper end that is closer to the second side 116 of the main body 112 than the lower end of the first cylindrical region 118.

In some implementations, the main body 112 may include a plurality of lift pin holes 164 that may extend through the main body 112, thereby allowing lift pins (not shown) to be extended through the main body 112 and past the first side 114 of the main body 112 (or to allow the main body 112 to be lowered such that the lift pins, which may remain stationary, may protrude from the first side 114 of the main body) so as to allow a semiconductor wafer (also not shown) supported by the pedestal 104 to be lifted clear of, or lowered onto, the first side 114 of the main body 112.

In some additional or further implementations, the main body 112 may also include internal gas distribution passages 156 which may be used to distribute a gas, e.g., a non-reactive purge gas, to the underside of a semiconductor wafer being supported by the pedestal 104. The gas distribution passages 156 may, for example, connect with gas ports (not shown, but see later Figures) that lead to the first side 114 of the main body.

The stem 110 may, as noted earlier, support the main body 112 within the semiconductor processing chamber. The stem 110 may also, however, serve as a conduit through which various elements may pass. For example, the one or more cooling passage segments 134 may be connected with an inlet passage 146 and an outlet passage 148 that are configured to supply and receive, respectively, cooling fluid to and from the one or more cooling passage segments 134. Similarly, the one or more heating element segments 122 may be provided power via heating element power cables 144. Cables for one or more thermocouples 132 may be routed through the stem 110 as well. The one or more thermocouples 132 (or other temperature sensors, e.g., thermistors) may be placed into contact with, for example, a portion of the main body to allow for real-time monitoring of the temperature of the main body. In particular, the one or more thermocouples 132 may be connected with the main body 112 at a location or locations that are proximate to the first side 114 of the main body 112, thereby allowing the temperature of the main body 112 near where wafers would be supported by the main body 112 to be monitored.

If the pedestal 104 is equipped with gas distribution passages 156, then the stem 110 may also include a gas supply line that delivers the non-reactive gas to be distributed via the gas distribution passages 156 to the gas distribution passages 156. Alternatively, the interior of the stem 110 may be sealed, with the gas distribution passages 156 providing the only exit flow path, and such a gas simply flowed into the interior of the stem 110, e.g., near the bottom, and then exiting the stem 110 via the gas distribution passages 156.

As will be apparent from later Figures, the heating element power cable 144 pair and the inlet passage 146/outlet passage 148 pair may be oriented such that they are approximately 90° out of phase with one another, thus allowing each of the heating element power cables 144, the inlet passage 146, and the outlet passage 148 to extend downward through a different quadrant of the stem 110. Cabling for the one or more thermocouples 132, if used, may optionally be routed down the center of the stem 110. Such an arrangement allows the stem 110 to be kept at a small diameter, thereby making it suitable for use with equipment developed for pedestals lacking both active heating and active cooling systems. It will be understood that other types of temperature sensor, e.g., thermistors, resistive temperature sensors, etc., may also be used in place of, or in addition to, the thermocouples for purpose of measuring pedestal temperatures.

It will be understood that while the implementation depicted in FIG. 1 features a multi-piece main body 112, other implementations of the main body may be manufactured in a way that requires fewer pieces or even as a single-piece. For example, the main body 112 may be additively manufactured, with the third portion 112c and the second portion 112b being formed as a single, contiguous part with the one or more cooling passage segments 134 formed within. In a further or additional example, the second portion 112b and the first portion 112a may similarly be formed as a single contiguous part around the one or more heating element segments 122.

It will also be understood that one or more of the first portion 112a, the second portion 112b, and the third portion 112c may, in turn, be a multi-layer component or assembly. For example, the first portion 112a may be provided by bonding two or more different components together, e.g., a thin, ceramic top plate may be bonded to or otherwise attached to a larger, aluminum plate, with the two components collectively forming the first portion 112a. In some implementations, one or more of the first portion 112a, the second portion 112b, and the third portion 112c may be connected together via threaded connections, e.g., one of the portions may have threaded holes or holes with threaded inserts, and another portion or portions may have through-holes through which threaded fasteners, e.g., screws, may be inserted. The through-holes may be aligned with the threaded holes to allow the threaded fasteners to be screwed into the threaded holes, thereby clamping the portions together.

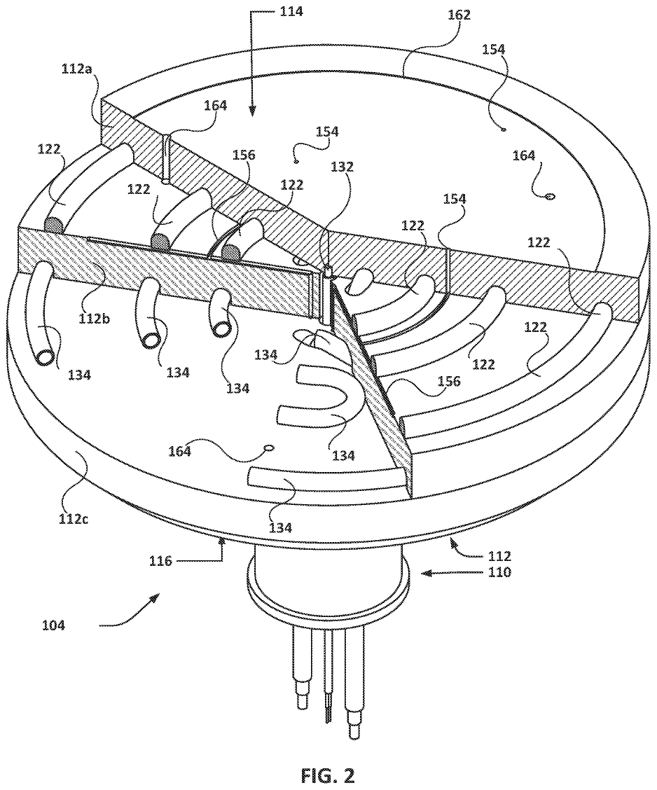

FIG. 2 depicts an isometric cutaway view of the pedestal 104 of FIG. 1. In FIG. 2, the first portion 112a is shown with slightly more than half cut away, while the second portion 112b is shown about one third cut away. The one or more heating element segments 122 are shown cut away to the same extent as the second portion 112b, while the one or more cooling passage segments 134 are shown cut away to a somewhat lesser extent than the second portion 112b.

As can be seen more clearly in FIG. 2, the gas distribution passages 156, if present, may be connected with gas ports 154 that allow gas that is delivered to the gas distribution passages 156 (e.g., via the gas inlets 158 near the center of the second and third portions 112b/c) to be distributed to locations in the first side 114 of the main body 112.

As can be seen in FIG. 2, the one or more cooling passage segments 134 are tubular, e.g., provided using a stainless steel tube having an annular cross-section, that has been bent so as to follow a particular path. Thus, the one or more cooling passage segments 134 may be a structure that is discrete or separate from, but trapped within, the main body 112. However, as noted earlier, other implementations may simply provide the one or more cooling passage segments by way of features that are formed directly in the material of the main body 112.

The heating element segments 122 may similarly be a component or components that are separate from, but embedded within, the main body 112. For example, the heating element segments 122 may be a resistive heating element, portions of a resistive heating element, or resistive heating elements that are trapped within a channel or groove provided in the first portion 112a and/or second portion 112b. As shown, the heating element segments 122 have a U-or D-shaped cross-section within the first cylindrical region 118 such that they are able to conform to a U-or D-shaped heating element channel that is machined into the first portion 112a, thereby providing good thermal contact between the one or more heating element segments 122 and the main body 112. In other implementations, the resistive heating element(s) that may be at the core of the one or more heating element segments may have a round cross-section. In some implementations, an epoxy or other liquid-phase material that may be cured into a solid or non-liquid phase may be applied to the interface between the one or more heating element segments 122 and the first portion 112a and/or the second portion 112b in order to both secure the one or more heating element segments 122 in place relative to the main body 112 and provide a more thermally conductive interface between the one or more heating element segments 122 and the main body 112.

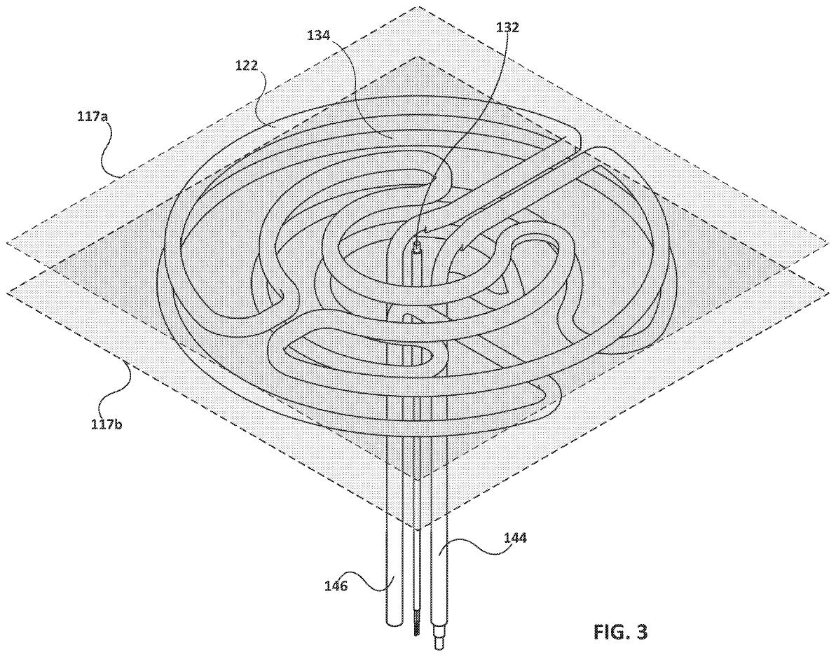

FIG. 3 depicts the one or more heating element segments 122 and the one or more cooling passage segments 134 in isolation, i.e., without the main body 112 present. As can be seen, both the one or more heating element segments 122 and the one or more cooling passage segments 134 follow paths that lie in two parallel planes 117a and 117b, respectively, and which meander across a circular area encompassed by the main body 112. The particular paths followed by the heating element segments 122 and the cooling passage segments 134 depicted in the example pedestal 104, it will be understood, represent a particular configuration that may provide an optimal or near-optimal thermal uniformity and thermal transient behavior.

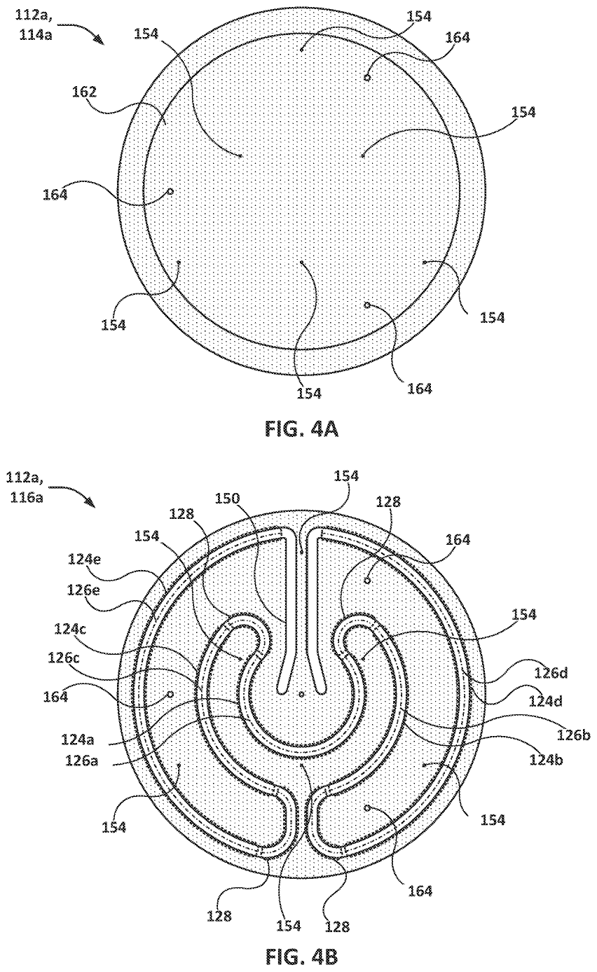

FIGS. 4A through 6B depict top and bottom views of each portion 112a, 112b, and 112c, respectively. For example, in FIG. 4A, the first side 114a of the first portion 112a is shown, while in FIG. 4B, the second side 116a of the first portion 112a is shown. As can be seen in FIG. 4A, the first side 114a of the first portion 112a serves as the first side 114 of the main body 112 and has a wafer recess 162 in the middle. The wafer recess 162 may, for example, be a circular recessed region in the middle of the first side 114 of the main body 112 that is sized slightly larger than a diameter of the semiconductor wafers that are intended to be supported by the pedestal 104. In other implementations, there may be no wafer recess 162 or, alternatively a raised circular region sized approximately the same diameter as such semiconductor wafers may be provided in the first side 114 of the main body 112. Also visible in FIG. 4A are the lift pin holes 164 and gas ports 154 discussed earlier.

As can be seen in FIG. 4B, the second side 116a of the first portion 112a has a heating element channel 150 machined or formed in it that houses the one or more heating elements segments 122 (not explicitly shown here, but understood to be present within the heating element channel 150), which may, in some implementations, include a plurality of arcuate heating element segments. In some implementations two or more, or potentially all, of the arcuate heating element segments may be concentric with one another. For example, the arcuate heating element segments 122 may include a first arcuate heating element segment 124a that extends along a first arcuate heating path 126a, a second arcuate heating element segment 124b that extends along a second arcuate heating path 126b, and a third arcuate heating element segment 124c that extends along a third arcuate heating path 126c. In such an implementation, the first arcuate heating path 126a may have a radius that is smaller than the radii of the second arcuate heating path 126b and the third arcuate heating path 126c; in some further such implementations, the second arcuate heating path 126b and the third arcuate heating path 126c may be equal.

In some further such implementations, the plurality of arcuate heating elements may further include a fourth arcuate heating element segment 124d that extends along a fourth arcuate heating path 126d and a fifth arcuate heating element segment 124e that extends along a fifth arcuate heating path 126e. In such implementations, the radii of the second arcuate heating path 126b and the third arcuate heating path 126c may be less than the radii of the fourth arcuate heating path 126d and the fifth arcuate heating path 126e. In some such implementations, the radii of the fourth arcuate heating path 126d and the fifth arcuate heating path 126e may be equal.

The various arcuate heating element segments discussed above may, in some cases, be joined by bridging heating element segments 128 that extend between endpoints of pairs of the arcuate heating paths 126a-c or 126a-e, thereby forming a continuous chain of heating element segments 122.

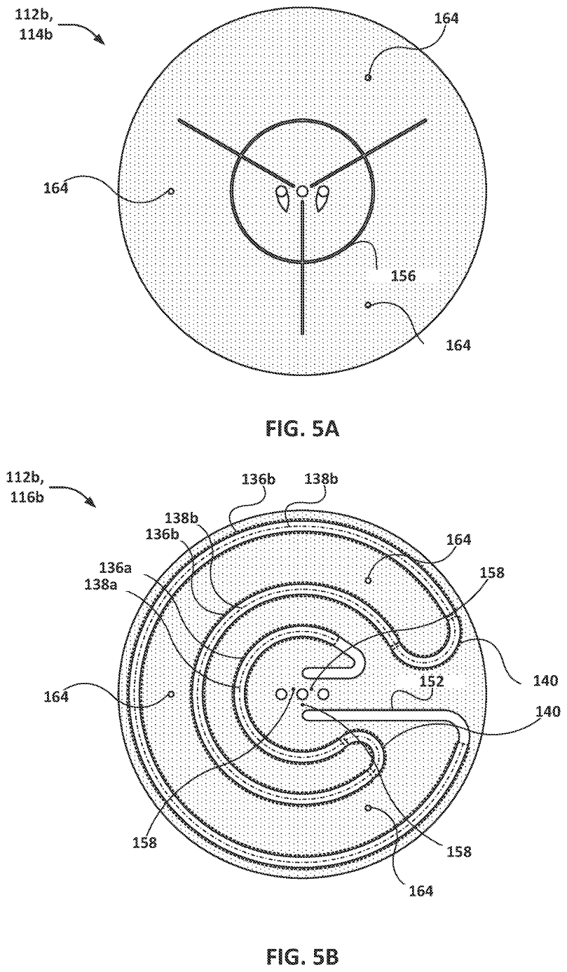

In FIG. 5A, the first side 114b of the second portion 112b is shown. The lift pin holes 164 extend all the way through the main body 112 and are thus also present in the second portion 112b as well, as shown in FIG. 5A. Also visible in FIG. 5A are the gas distribution passages 156 which, in this example, include a circular portion and three radial portions that may be used to distribute non-reactive gas to the underside of a semiconductor wafer placed on the first side 114 of the main body 112. Such non-reactive gas may be introduced to the gas distribution passages 156 via, for example, one or more gas inlets 158.

FIG. 5B shows the second side 116b of the second portion 112b. Somewhat similar to heating element channel 150 of the first portion 112a, the second portion 112b has a cooling passage channel 152 that is machined or formed in the second side 116b of the second portion 112b. The cooling passage channel 152 may house the one or more cooling passage segments 134 (not explicitly shown here, but understood to be present within the cooling passage channel 152) which may, in some implementations, include a plurality of arcuate cooling passage segments 134. In some such implementations, two or more, or sometimes all, of the arcuate cooling passage segments 134 may be concentric with one another. For example, the arcuate cooling passage segments 134 may include a first arcuate cooling passage segment 136a that extends along a first arcuate cooling path 138a and a second arcuate cooling passage segment 136b that extends along a second arcuate cooling path 138b. In such an implementation, the first arcuate cooling path 138a may have a radius that is smaller than the radius of the second arcuate cooling path 138b.

In some implementations, the plurality of arcuate cooling passage segments may further include a third arcuate cooling passage segment 136c that extends along a third arcuate cooling path 138c. In such implementations, the second arcuate cooling path 138b may have a radius that is smaller than the radius of the third arcuate cooling path 138c.

The various arcuate cooling passage segments discussed above may, in some cases, be joined by bridging cooling passage segments 140 that extend between endpoints of pairs of the arcuate cooling paths 138a and 138b or the arcuate cooling paths 138a-c, thereby forming a continuous chain of cooling passage segments 134.

In the depicted example, coolant may be flowed into the plurality of cooling passage segments 134 such that the coolant flows into the third arcuate cooling passage segment 136c and then flows into the second arcuate cooling passage segment 136b and then into the first arcuate cooling passage segment 136a. Such a configuration may provide a larger amount of cooling near the periphery of the second portion 112b and decreasing amounts of the cooling near the center of the second portion 112b.

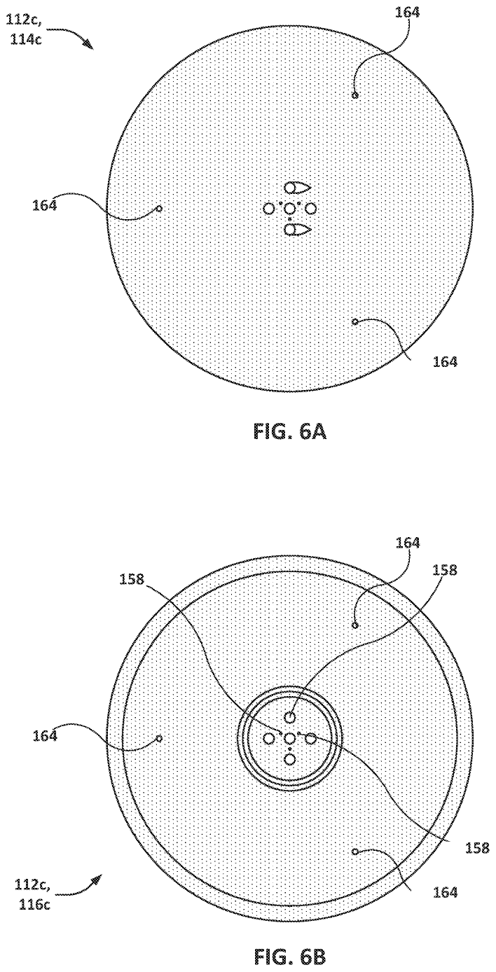

FIG. 6A depicts a top view showing the first side 114c of the third portion 112c, while FIG. 6B depicts a bottom view showing the second side 116c of the third portion 112c. As can be seen, the lift pin holes 164 extend through the third portion 112c as well.

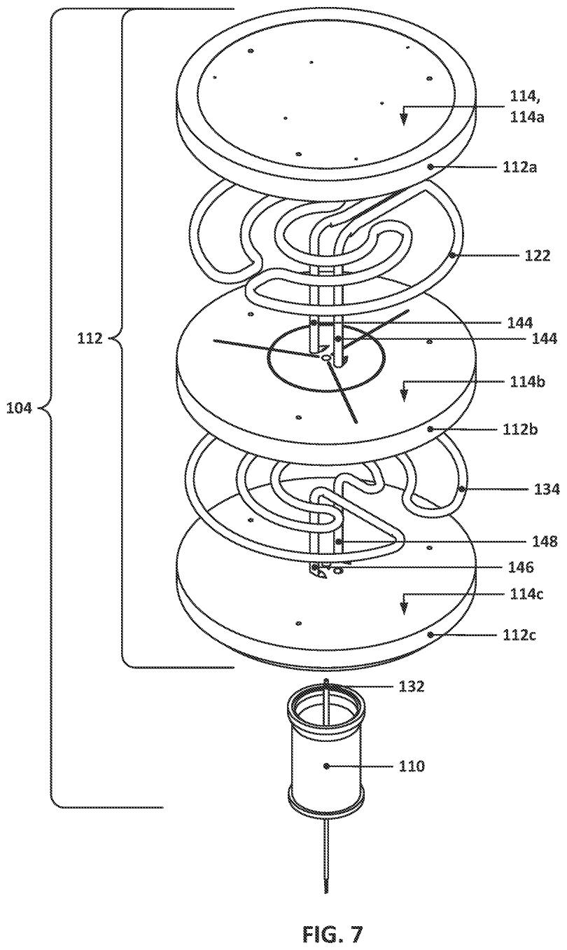

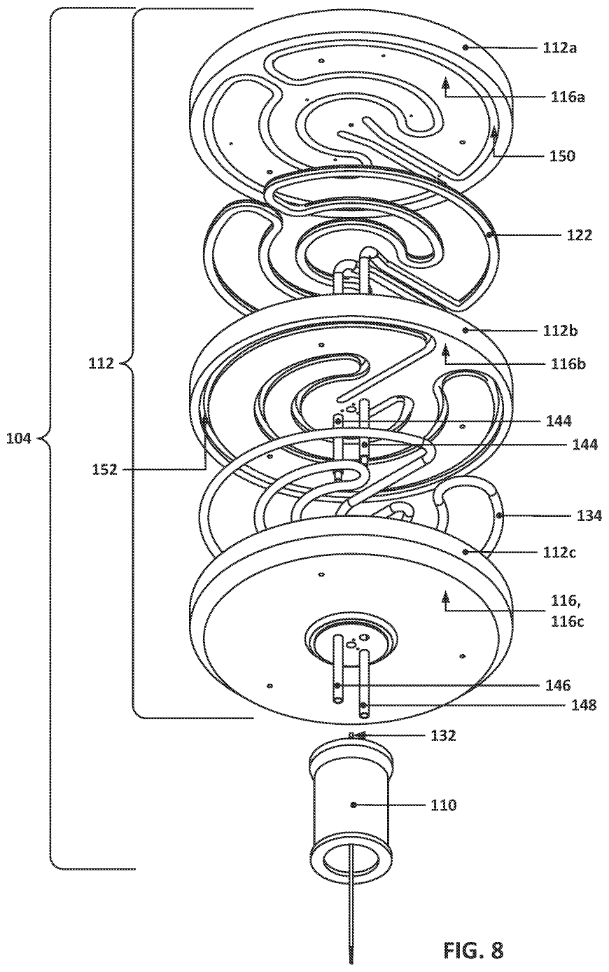

As noted earlier, the first portion 112a, the second portion 112b, and the third portion 112c may be connected or otherwise fused together, e.g., through brazed or bonded connections, such that the first portion 112a, the second portion 112b, and the third portion 112c, in effect, form a contiguous thermal mass, thereby allowing for rapid heat transfer from the one or more heating element segments 122 to the one or more cooling passage segments. FIGS. 7 and 8 show isometric exploded views of the pedestal 104, showing how the one or more heating element segments 122 may be inserted within the heating element channel 150 and the one or more cooling passage segments 134 may be inserted within the cooling passage channel 152 before the first portion 112a, the second portion 112b, and the third portion 112c are connected together and with the stem 110.

It will be appreciated that while the heating element channel 150 and the cooling passage channel 152 are both shown as being located in the second sides 116a and 116b of the first portion 112a and the second portion 112b, either or both of the heating element channel 150 and the cooling passage channel 152 may be located in the first sides 114b and/or 114c of the second portion 112b and the third portion 112c, respectively. In some implementations, either or both of the heating element channel 150 and the cooling passage channel 152 may be formed in both the first sides 114b and 114c and the second sides 116a and 116b of the first portion 112a, the second portion 112b, and the third portion 112c.

The main body 112 (for example, the first portion 112a, the second portion 112b, and the third portion 112c, if a multi-piece main body 112 is used) of the pedestal 104 may, for example, be made of an aluminum alloy. The high thermal conductivity of aluminum allows for heat to be quickly transferred into or out of the main body, thereby allowing for rapid changes in temperature.

The coolant that is flowed through the one or more cooling passage segments may, for example, be a liquid, such as water, glycol, or a perfluorinated, inert, polyether liquid such as Galden® (offered by the Solvay Specialty Polymers).

Pedestals such as those discussed herein may be used in semiconductor process chambers in which the pedestals must be able to support a wide range of temperatures. For example, a pedestal may need to be able to be heated (or have a wafer-supporting surface thereof heated) to up to 400° C. during one phase of a semiconductor process, but may also need to be cooled to a much lower temperature, e.g., 10° C., 40° C., or 50° C., during another phase of the same semiconductor process (e.g., with the wafer remaining on the pedestal in between the two phases). Such temperatures may need to be achieved while the chamber housing itself (or its interior walls) is kept at a higher temperature, e.g., 80° C., 90° C., 100° C., 110° C., 120° C., 130° C., 140° C., or 150° C. By incorporating both heating and cooling functionality within the pedestal, pedestals such as those disclosed herein may have the capability to provide pedestal temperatures such as those discussed above when used in elevated-temperature chambers, e.g., chambers in which the chamber wall temperatures are higher than the desired pedestal temperatures during some phases of semiconductor processing.

Such configurations provide several additional benefits as well. For example, when power to the one or more heating element segments 122 is decreased or stopped, e.g., in order to reduce the temperature of the first side 114 of the main body 112, the cooling that is provided by way of the one or more cooling passage segments 134 may be used to more rapidly lower the temperature of the first portion 112a and the first side 114 of the main body 112. Similarly, when it is desired to heat the first side 114 of the main body 112, the flow of coolant through the one or more cooling passage segments 134 may be ceased or slowed in order to decrease the amount of active cooling that the one or more cooling passage segments 134 provide, thereby allowing the heat that may be provided by the one or more heating element segments 122 to more effectively heat the first side 114 of the main body 112. This allows the first side 114 of the main body 112 to be rapidly heated from a lower temperature to a higher temperature. A pedestal 104 that incorporates such features may be used in semiconductor processing tools in which semiconductor wafers are processed using semiconductor processing operations that require sequential operations that are performed with the semiconductor wafers at different temperatures. In such processes, the time required to increase or decrease the temperature of such a semiconductor wafer may be a significant contributor to the total amount of time required to complete the semiconductor processing operation. In such situations, using a pedestal 104 with features such as those discussed above may allow such heating and/or cooling operations to be performed more quickly, thereby reducing the contribution that such heating/cooling may make to the total amount of time required to complete the semiconductor processing operation. This reduces the overall duration of such semiconductor processing operations, thereby allowing more semiconductor wafers to be processed in the same window of time and increasing wafer processing throughput.

Another benefit is that when power is applied to the one or more heating element segments 122 in order to generate heat, coolant may simultaneously be flowed through the one or more cooling passage segments 134. This has the effect of siphoning the heat from the one or more heating element segments 122 that is directed into the region of the main body 112 in between the one or more heating element segments 122 and the one or more cooling passage segments 134, thereby allowing the first side 114 of the main body 112 to be heated to a relatively high temperature, e.g., 200° C. to 400° C., while the remainder of the main body 112 is kept at a lower temperature. This may allow the temperature of the stem 110 to be kept lower than the temperature of the top of the main body 112. This may avoid the potentially hazardous condition in which the stem 110, which may protrude out of the bottom of the chamber, is at a temperature that is considered to be dangerous to humans that may be in the vicinity or that may pose a risk to components in close proximity to the stem 110, such as elastomeric seals that may be used to seal to the stem 110 or other nearby components and which may be damaged, e.g., melt, when exposed to high temperatures.

Such pedestals may also be used to heat wafers to a desired temperature with a higher degree of accuracy than may be obtained with other types of pedestal heating systems, particularly in the context of certain types of semiconductor processing chambers and processes in which the pedestal temperature (and thus wafer temperature) may need to be kept at a less elevated temperature, e.g., at temperatures between 50°to 200° C. In many contexts where a heated pedestal is used in a semiconductor processing chamber, the target temperature that such pedestals are intended to operate at may be in the 300° C. to 400° C. range or higher. Such elevated temperatures are generally outside the range that heat transfer fluids suitable for use in semiconductor processing systems, such as Galden® (max temperatures of less than 300° C.) or glycols (max temperatures of less than 200° C.), can operate at without degrading or otherwise becoming compromised. Accordingly, pedestals that are intended to operate at such elevated temperatures generally utilize resistive heating elements in order to reach and maintain these elevated temperatures.

At the same time, the surrounding environment, e.g., the process chamber and/or other components within the process chamber, is typically at a much lower temperature, e.g., 100° C. to 300° C. lower. As a result of the large difference in temperature between such pedestals and their surrounding environment, significant heat transfer via radiative, convective, and conductive heat transfer mechanisms occurs (and particularly via radiative heat transfer mechanisms). Accordingly, the temperature control system for the pedestal must work constantly to keep such pedestals at a desired target temperature, as heat that is transferred into such a pedestal by an integrated heater system will rapidly dissipate due to the large temperature differences that are present. In order to maintain such pedestals at the desired target temperature, the resistive heater systems in such pedestals are typically powered on until the pedestal temperature rises to a specified upper temperature threshold (as measured by one or more temperature sensors in the pedestal, for example), at which point the power to the resistive heater system(s) is stopped. At this point, the pedestal will start to cool down, and the resistive heater may be powered on again when the pedestal temperature reaches a specified lower temperature threshold and the cycle repeated. Due to the rapid heat loss in such systems, the resistive heaters may generally operate at a high duty cycle, and any overshoots in temperature that may occur at the tail end of a duty cycle may take a relatively short amount of time to drop back into the target temperature range.

However, when such pedestals are used in the context of lower temperature ranges, e.g., in the 50° C. to 200° C. range, the rate of heat transfer—and particularly the rate of radiative heat transfer—may be much lower than at the elevated temperatures discussed above. It may thus require much less engagement of the resistive heaters in order to maintain such lower temperatures. Somewhat unexpectedly, it is at the same time more difficult to accurately maintain such pedestals, e.g., aluminum pedestals, at a specific target temperature within such a lower temperature range since any overshoots in temperature that may occur may take much longer to drop back into the target temperature range due to the reduced rate at which such a pedestal will cool at such lower temperatures.—as a result, the pedestal temperature may be higher than the desired target temperature a much larger percentage of the time due to overshoots as would normally be the case if the pedestal in question were being maintained at a much higher temperature, e.g., at temperatures of 300° C. or higher.

The pedestals discussed herein may, however, be operated so as to provide highly stable temperature control at lower elevated temperatures, e.g., in the 50° C. to 200° C. range. For example, if the coolant that is flowed through the cooling passage segments is kept at a temperature that is somewhat cooler than the target temperature, e.g., within 50° C. of and below the target temperature, within 40° C. of and below the target temperature, within 30° C. of and below the target temperature, within 20° C. of and below the target temperature, within 15° C. of and below the target temperature, within 14° C. of and below the target temperature, within 13° C. of and below the target temperature, within 12° C. of and below the target temperature, within 11° C. of and below the target temperature, within 10° C. of and below the target temperature, within 9° C. of and below the target temperature, within 8° C. of and below the target temperature, within 7° C. of and below the target temperature, within 6° C. of and below the target temperature, or within 5° C. of and below the target temperature, the coolant (even if at a temperature that is close to the target temperature, e.g., within 5° C. of and below or within 10° C. of and below the target temperature) may act to rapidly cool the pedestal in the event that heating provided by the resistive heater causes the temperature of the pedestal to overshoot the target temperature. In some implementations, the coolant may additionally be kept to at least 5° C. cooler than the target temperature.

In many cases, the coolant passage segments and the heater segments may, in effect, operate as a two-stage temperature-control system. For example, the coolant passage segments may act as a first temperature-control mechanism that may act as a heater when the temperature of the bulk material of the pedestal in the area around the coolant passage segments is below the coolant temperature but may act as a cooler when the temperature of the bulk material of the pedestal in the area around the coolant passage segments is above the coolant temperature. Similarly, the heater segments may act as a second temperature-control mechanism that generally only functions in a heating capacity, e.g., capable of adding heat to the pedestal but not capable of removing heat from the pedestal.

In such implementations, the first temperature-control mechanism may be used to perform bulk heating of the pedestal in order to bring the pedestal to a temperature close to, but not over, the target temperature, e.g., to within 10° C. of the target temperature, and then the second temperature-control mechanism may be used to deliver additional heat to the pedestal in order to further heat the pedestal to the target temperature, e.g., heating the pedestal the last 10° C., for example. In the event that the second temperature-control mechanism, i.e., the heater segments, deliver too much power to the pedestal and cause the pedestal temperature to overshoot the target temperature, the first temperature-control mechanism may then remove the excess heat from the pedestal to more rapidly cool the pedestal down to the target temperature. This reduces the amount of time that the temperature of the pedestal may be above the target temperature and results in a more stable temperature at the wafer-pedestal interface than can be obtained without using the first temperature-control mechanism in this way.

The first temperature-control mechanism, in effect, provides a temperature control system that is able to both heat and cool the pedestal to the coolant temperature relatively rapidly, but which may have lower accuracy since it is difficult to rapidly change the coolant temperature in order to address potential transient heating or cooling events in the pedestal. As such, the first temperature-control mechanism by itself would provide relatively poor temperature control. For example, if only the first temperature-control mechanism were to be used to keep the pedestal at a target temperature, process conditions within the chamber that result in additional heat temporarily being delivered to the pedestal for some duration of time, e.g., from a plasma that may be formed within the chamber above the pedestal, may require that the coolant temperature be dropped somewhat to offset the increased heat load. However, this may take time, as the coolant will generally be supplied from an external reservoir or source that includes a volume of coolant that is typically multiple times larger than the volume of coolant that is within the cooling passage segments at any one instant in time. If the temperature of the coolant is to be changed, it is typically necessary to do so by heating or cooling the entire coolant volume, which takes time.

The second temperature-control mechanism, in contrast, provides a rapid response time and is able to switch between a heating mode and a non-heating mode much more quickly that would be possible with the first temperature-control mechanism. The second temperature-control mechanism, however, is only able to provide that rapid response time for heating, not cooling.

By integrating both the first temperature-control mechanism and the second temperature-control mechanism into the pedestal, the benefits of both temperature-control mechanisms may be taken advantage of in order to provide an integrated temperature-control system that is able to provide rapid response for both heating and cooling, even in lower-temperature regimes in which radiative cooling results in a much lower amount of heat loss.

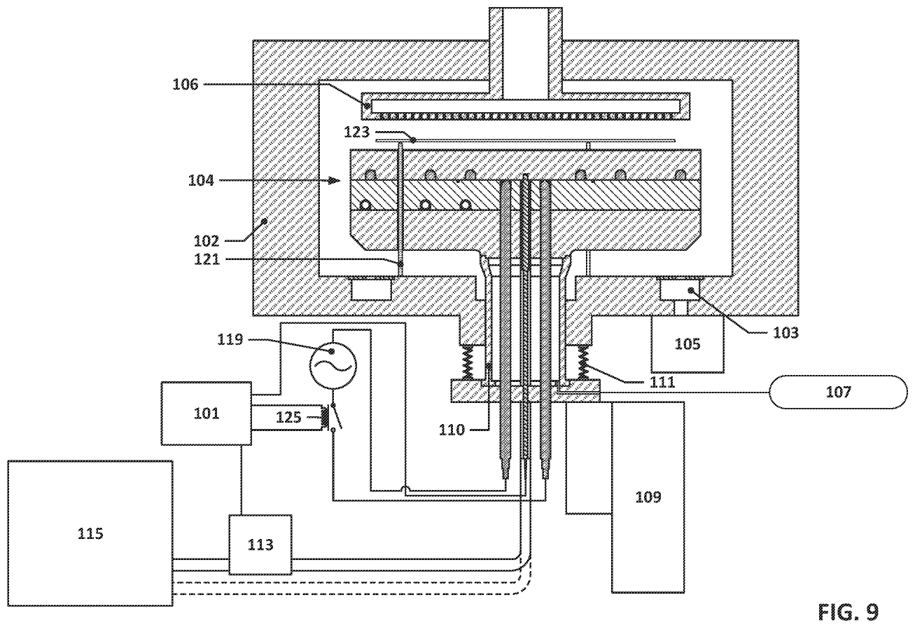

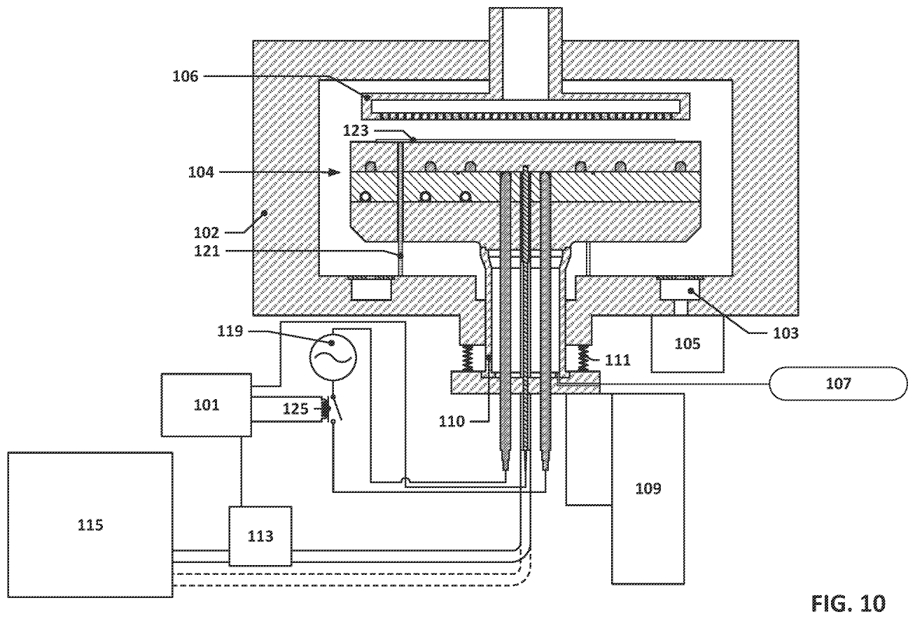

FIGS. 9 and 10 depict schematics of a semiconductor processing tool featuring a pedestal such as that shown in FIG. 1. The semiconductor processing tool may include a semiconductor processing chamber 102 that has an internal volume within it that houses a showerhead 106 and the pedestal 104. The stem of the pedestal 104 may extend through an aperture in the bottom of the semiconductor processing chamber 102 and may, in some cases, be connected with a vertical lift mechanism 109, which may be controlled so as to raise and/or lower the pedestal 104 relative to the semiconductor processing chamber 102. FIG. 9 depicts the pedestal 104 in a lowered position relative to the semiconductor processing chamber 102 and FIG. 10 depicts the pedestal 104 in a raised position relative to the semiconductor processing chamber 102. The semiconductor processing chamber 102 may, for example, include lift pins 121 that extend upwards through the lift pin holes 164 in the pedestal 104. The lift pins 121 may act to support a semiconductor wafer 123 when the pedestal 104 is in the lowered position, thereby providing a gap between the semiconductor wafer 123 and the pedestal 104 into which an end effector of a wafer handling robot (not shown) can be inserted in order to place or retrieve the semiconductor wafer from the semiconductor processing chamber 102. When the pedestal is in the raised position, e.g., as shown in FIG. 10, the semiconductor wafer 123 may instead rest directly on the first side 114 of the main body 112 of the pedestal 104. One or more process gases may then be flowed across the semiconductor wafer 123 via the showerhead 106, e.g., the showerhead 106 may have a plurality of small gas distribution ports distributed across its underside that act to deliver such process gases across the semiconductor wafer 123 during wafer processing operations. In some implementations, the showerhead 106 and/or the pedestal 104 may serve as electrodes that are used to deliver radio-frequency power to gases that may be in the gap between the showerhead 106 and the pedestal 104, thereby allowing a plasma to be generated and used during wafer processing operations.

Gases that are introduced into the semiconductor processing chamber 102 during wafer processing operations may be evacuated from the semiconductor processing chamber 102 via an exhaust system, e.g., the semiconductor processing chamber 102 may have an annular exhaust plenum 103 underneath the pedestal 104 that is connected with a vacuum pump 105, thereby allowing gases to be drawn out of the semiconductor processing chamber 102 in a more or less azimuthally uniform manner.

As noted above, the pedestal 104 may be configured to move up and down vertically relative to the semiconductor processing chamber 102. A bellows seal 111 may be provided to seal between the semiconductor processing chamber 102 and the stem 110 (or a component connected therewith). In this example, the stem 110 is connected with a baseplate that caps off the stem 110, thereby sealing the interior volume of the stem 110 such that non-reactive gas provided by non-reactive gas source 107 and introduced into the interior of the stem 110 must flow up through the stem 110 and out of the pedestal 104 via the gas ports 154 in the first side 114 of the main body 112 of the pedestal 104. However, in other implementations, e.g., in which there is not non-reactive gas supplied to the main body 112 or in which non-reactive gas is supplied to the main body 112 but via a gas feed line that extends to the main body 112, the stem 110 may be open on the bottom, e.g., in equilibrium with the surrounding atmosphere.

The inlet passage 146 and the outlet passage 148 may be fluidically connected with a coolant reservoir 115 (which may incorporate a heat exchanger). A coolant pump 113 may be connected with one of the inlet passage 146 and the outlet passage 148 and used to circulate coolant from the coolant reservoir 115 through the one or more cooling passage segments 134 in the pedestal 104.

Somewhat similarly, the heating element power cables 144 may be electrically connected with a power source 119. A relay or other power-regulating device may be included to allow the amount of power directed to the one or more heating element segments 122 to be controlled by a controller 101. The controller 101 may also be communicatively connected with the coolant pump 113 to allow the controller 101 to control the flow of coolant through the one or more coolant passage segments. The one or more thermocouples 132, if present, may also be communicatively coupled with the controller 101 as well. The controller, for example, may control the coolant pump 113 and the power delivery to the one or more heating element segments in order to cool, heat, or maintain the pedestal 104 at or to a particular temperature.

In some implementations, e.g., atomic layer etch tools, the main body 112 and/or the stem 110 may be coated with an anti-corrosion coating to reduce the potential for metal contamination on the wafers being processed due to the material of the main body 112 and/or the stem 110 being etched away. Such coatings may, for example, include anodized coatings, such as hard anodized coatings, plating, coatings of materials applied via atomic layer deposition, e.g., in another chamber or in the same chamber as the wafer is processed within. In some instances, such coatings may include silicon oxide coatings, aluminum oxide coatings, or other ceramic coatings. In yet other instances, such coatings may include plating, such as nickel plating.

The controller 101, depending on the processing requirements and/or the type of system, may be programmed to control any of the processes disclosed herein, such as processes for controlling the pedestal, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

For example, the controller may be configured to maintain the pedestal temperature at a setpoint temperature or range of temperatures (referred to hereinafter simply as a setpoint temperature, which will be understood to refer to both a single desired temperature or a desired range of temperatures) within a range of between 50° C. and 200° C., as discussed earlier above. The setpoint temperature may, for example, be a temperature, or a temperature range, that is within 50° C.-55° C., within 55° C.-60° C., within 60° C.-65° C., within 65° C.-70° C., within 70° C.-75° C., within 75° C.-80° C., within 80° C.-85° C., within 85° C.-90° C., within 90° C.-95° C., within 95° C.-100° C., within 100° C.-105° C., within 105° C.-110° C., within 110° C.-115° C., within 115° C.-120° C., within 120° C.-125° C., within 125° C.-130° C., within 130° C.-135° C., within 135° C.-140° C., within 140° C.-145° C., within 145° C.-150° C., within 150° C.-155° C., within 155° C.-160° C., within 160° C.-165° C., within 165° C.-170° C., within 170° C.-175° C., within 175° C.-180° C., within 180° C.-185° C., within 185° C.-190° C., within 190° C.-195° C., or within 195° C.-200° C., for example.

In order to do so, the controller may cause one or more heat exchangers and/or one or more heaters and/or one or more chillers (forming, for example, a temperature control system) in, or connected with, the reservoir 115 to heat and/or cool the coolant that is in the reservoir to a temperature that is 50° C. or less below the setpoint temperature or temperature range, e.g., within 40° C. of and below the setpoint temperature or temperature range, within 30° C. of and below the setpoint temperature or temperature range, within 20° C. of and below the setpoint temperature or temperature range, within 15° C. of and below the setpoint temperature or temperature range, within 14° C. of and below the setpoint temperature or temperature range, within 13° C. of and below the setpoint temperature or temperature range, within 12° C. of and below the setpoint temperature or temperature range, within 11° C. of and below the setpoint temperature or temperature range, within 10° C. of and below the setpoint temperature or temperature range, within 9° C. of and below the setpoint temperature or temperature range, within 8° C. of and below the setpoint temperature or temperature range, within 7° C. of and below the setpoint temperature or temperature range, within 6° C. of and below the setpoint temperature or temperature range, within or 5° C. of and below the setpoint temperature or temperature range (with regard to the coolant being heated and/or cooled to a temperature of within XC and below a temperature range, it will be understood that this is inclusive of heating or cooling the coolant to XC below the setpoint temperature or the bottom end of the setpoint temperature range, as well as to temperatures in between XC and the setpoint temperature or the bottom end of the setpoint temperature range). In particular implementations, the controller may cause the heat exchanger and/or the heater in, or connected with, the reservoir 115 to heat and/or cool the coolant that is in the reservoir to a temperature that is 20° C. or less below the setpoint temperature or temperature range, e.g., 10° C. below the setpoint temperature or temperature range.

The controller may also control the power source 119 or, for example, relay or contactor 125, in order to control the application of power to the one or more heating element segments 122 that are within the pedestal. The controller, for example, may control the application of power to the one or more heating element segments 122 such that when a measured temperature of the pedestal 104, e.g., as measured by the thermocouple 132 or similar temperature measurement sensor(s), falls below a specified first threshold temperature, e.g., a temperature higher than the temperature that the coolant is controlled to be at but lower than the setpoint temperature or temperature range, power is caused to be applied to the one or more heater element segments 122 until the temperature sensor(s) indicate that a second threshold temperature is reached, e.g., the setpoint temperature or a temperature associated with the setpoint temperature range (for example, the upper end of the setpoint temperature range). In some instances, the first threshold temperature may be the bottom end of the setpoint temperature range (if a range is used), while the second threshold temperature may be at the top end of the setpoint temperature range. In other implementations, the first and/or second threshold temperatures may be set above the bottom end and below the top end, respectively, of the setpoint temperature range.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application-specific integrated circuits (ASICs), and/or one or more microprocessors or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example pedestals according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. However, this disclose at the very least is directed to the following numbered implementations.
Implementation 1: An apparatus that includes a pedestal configured to support a semiconductor wafer during semiconductor processing operations, the pedestal including: a main body having a first side and a second side opposite the first side of the main body, one or more heating element segments disposed within the main body and within a first cylindrical region, one or more cooling passage segments disposed within the main body within a second cylindrical region, and a stem connected with the second side of the main body, in which the first cylindrical region is interposed between the second cylindrical region and the first side of the main body and the second cylindrical region is interposed between the first cylindrical region and the second side of the main body.
Implementation 2: The apparatus of implementation 1, in which the one or more heating element segments is a plurality of heating element segments and the plurality of heating element segments includes a plurality of arcuate heating element segments.
Implementation 3: The apparatus of implementation 2, in which the arcuate heating element segments are concentric with one another.
Implementation 4: The apparatus of implementation 2, in which the plurality of arcuate heating element segments includes a first heating element segment extending along a first arcuate heating path, a second heating element segment extending along a second arcuate heating path, and a third heating element segment extending along a third arcuate heating path and in which the first arcuate heating path has a radius less than a radius of the second arcuate heating path and less than a radius of the third arcuate heating path.
Implementation 5: The apparatus of implementation 4, in which the first arcuate heating path, the second arcuate heating path, and the third arcuate heating path are concentric with one another.
Implementation 6: The apparatus of implementation 4, in which the radius of the second arcuate heating path is equal to the radius of the third arcuate heating path.
Implementation 7: The apparatus of any of implementations 4 through 6, in which the plurality of heating element segments further includes a fourth heating element segment extending along a fourth arcuate heating path and a fifth heating element segment extending along a fifth arcuate heating path, and the radius of the second arcuate heating path and the radius of the third arcuate heating path are less than a radius of the fourth arcuate heating path and a radius of the fifth arcuate heating path.
Implementation 8: The apparatus of implementation 7, in which the first arcuate heating path, the fourth arcuate heating path, and the fifth arcuate heating path are concentric with one another.
Implementation 9: The apparatus of implementation 7, in which the radius of the fourth arcuate heating path is equal to the radius of the fifth arcuate heating path.
Implementation 10: The apparatus of any of implementations 7 through 9, in which the first arcuate heating path, the second arcuate heating path, the third arcuate heating path, the fourth arcuate heating path, and the fifth arcuate heating path collectively define, at least in part, a plurality of arcuate heating paths, and in which the plurality of heating element segments further includes a plurality of bridging heating element segments, each bridging heating element segment extending between respective endpoints of a pair of adjacent arcuate heating paths in the plurality of arcuate heating paths.
Implementation 11: The apparatus of any of implementations 1 through 10, in which the one or more cooling passage segments is a plurality of cooling passage segments, and the plurality of cooling passage segments includes a plurality of arcuate cooling passage segments.
Implementation 12: The apparatus of implementation 11, in which the arcuate cooling passage segments are concentric with one another.
Implementation 13: The apparatus of implementation 11 or implementation 12, in which the plurality of arcuate cooling passage segments includes a first cooling passage segment extending along a first arcuate cooling path and a second cooling passage segment extending along a second arcuate cooling path, the first arcuate cooling path and the second arcuate cooling path are concentric with one another, and the first arcuate cooling path has a radius less than a radius of the second arcuate cooling path.
Implementation 14: The apparatus of implementation 13, in which the first arcuate cooling path and the second arcuate cooling path are concentric with one another.
Implementation 15: The apparatus of implementation 13 or implementation 14, in which the plurality of arcuate cooling passage segments further includes a third cooling passage segment extending along a third arcuate cooling path, the first arcuate cooling path and the third arcuate cooling path are concentric with one another, and the radius of the second arcuate cooling path is less than a radius of the third arcuate cooling path.
Implementation 16: The apparatus of implementation 15, in which the first arcuate cooling path and the third arcuate cooling path are concentric with one another.
Implementation 17: The apparatus of implementation 15, in which the first arcuate cooling path, the second arcuate cooling path, and the third arcuate cooling path collectively define, at least in part, a plurality of arcuate cooling paths, and the plurality of cooling passage segments further includes a plurality of bridging cooling passage segments, each bridging cooling passage segment extending between endpoints of two of the arcuate cooling paths in the plurality of arcuate cooling paths.
Implementation 18: The apparatus of any of implementations 1 through 17, in which the main body includes: a first portion having a first side and a second side, a second portion having a first side and a second side, and a third portion having a first side and a second side, and in which the second portion is interposed between the first portion and the third portion, the first side of the first portion is also the first side of the main body, the second side of the first portion is bonded to or fused to the first side of the second portion, and the second side of the second portion is bonded to or fused to the first side of the third portion.
Implementation 19: The apparatus of implementation 18, in which at least one of the second side of the first portion and the first side of the second portion includes a heating element channel, and the heating element channel houses the one or more heating element segments.
Implementation 20: The apparatus of any of implementations 1 through 19, in which the one or more heating element segments have a D-shaped cross-section.
Implementation 21: The apparatus of any of implementations 18 through 20, in which at least one of the second side of the second portion and the first side of the third portion includes a cooling passage channel, and the cooling passage channel houses the one or more cooling passage segments.
Implementation 22: The apparatus of any of implementations 18 through 21, in which the one or more cooling passage segments are tubular.
Implementation 23: The apparatus of implementation 22, in which the one or more cooling passage segments have an annular cross-section.
Implementation 24: The apparatus of implementation 18, in which the second side of the first portion is brazed to the first side of the second portion, and the second side of the second portion is brazed to the first side of the third portion.
Implementation 25: The apparatus of any of implementations 18 through 24, in which the first portion, the second portion, and the third portion are all made of an aluminum alloy.
Implementation 26: The apparatus of any of implementations 1 through 24, in which the main body is made of an aluminum alloy.
Implementation 27: The apparatus of any of implementations 1 through 26, further including a temperature sensor coupled with the main body.
Implementation 28: The apparatus of implementation 27, further including a power supply, a coolant reservoir having a temperature control system, a coolant pump, and a controller configured to: control the temperature control system to cause a coolant stored in the coolant reservoir to be maintained within a first temperature range that is between 5° C. and 50° C. below a setpoint temperature; control the coolant pump to cause the coolant to flow from the coolant reservoir and through the one or more cooling passage segments; and cause the one or more heating element segments to receive power from the power supply until the temperature sensor indicates that a temperature of the pedestal is at or greater than the setpoint temperature.

1. An apparatus for facilitating processing of semiconductor wafers, the apparatus comprising:
a pedestal configured to support a semiconductor wafer during semiconductor processing operations, the pedestal including:
a main body having a first side and a second side opposite the first side of the main body,
one or more heating element segments disposed within the main body and within a first cylindrical region,
one or more cooling passage segments disposed within the main body within a second cylindrical region, and
a stem connected with the second side of the main body, wherein:
the first cylindrical region is interposed between the second cylindrical region and the first side of the main body, and
the second cylindrical region is interposed between the first cylindrical region and the second side of the main body.

2. The apparatus of claim 1, wherein:
the one or more heating element segments is a plurality of heating element segments, and
the plurality of heating element segments includes a plurality of arcuate heating element segments.

3. The apparatus of claim 2, wherein:
the plurality of arcuate heating element segments comprises a first heating element segment extending along a first arcuate heating path, a second heating element segment extending along a second arcuate heating path, and a third heating element segment extending along a third arcuate heating path; and
the first arcuate heating path has a radius less than a radius of the second arcuate heating path and less than a radius of the third arcuate heating path.

4. The apparatus of claim 3, wherein:
the plurality of heating element segments further comprises a fourth heating element segment extending along a fourth arcuate heating path and a fifth heating element segment extending along a fifth arcuate heating path, and
the radius of the second arcuate heating path and the radius of the third arcuate heating path are less than a radius of the fourth arcuate heating path and a radius of the fifth arcuate heating path.

5. The apparatus of claim 4, wherein:
the first arcuate heating path, the second arcuate heating path, the third arcuate heating path, the fourth arcuate heating path, and the fifth arcuate heating path collectively define, at least in part, a plurality of arcuate heating paths, and
the plurality of heating element segments further comprises a plurality of bridging heating element segments, each bridging heating element segment extending between respective endpoints of a pair of adjacent arcuate heating paths in the plurality of arcuate heating paths.

6. The apparatus of claim 5, wherein:
the plurality of cooling passage segments comprises a first cooling passage segment extending along a first arcuate cooling path and a second cooling passage segment extending along a second arcuate cooling path;
the first arcuate cooling path and the second arcuate cooling path are concentric with one another; and
the first arcuate cooling path has a radius less than a radius of the second arcuate cooling path.

7. The apparatus of claim 6, wherein:
the plurality of cooling passage segments further comprises a third cooling passage segment extending along a third arcuate cooling path, and
the radius of the second arcuate cooling path is less than a radius of the third arcuate cooling path.

8. The apparatus of claim 7, wherein the first arcuate cooling path and the third arcuate cooling path are concentric with one another.

9. The apparatus of claim 7, wherein:
the first arcuate cooling path, the second arcuate cooling path, and the third arcuate cooling path collectively define, at least in part, a plurality of arcuate cooling paths, and
the plurality of cooling passage segments further comprises a plurality of bridging cooling passage segments, each bridging cooling passage segment extending between endpoints of two of the arcuate cooling paths in the plurality of arcuate cooling paths.

10. The apparatus of claim 1, wherein the main body includes:
a first portion having a first side and a second side,
a second portion having a first side and a second side, and
a third portion having a first side and a second side, and wherein:
the second portion is interposed between the first portion and the third portion,
the first side of the first portion is also the first side of the main body,
the second side of the first portion is bonded to or fused to the first side of the second portion, and
the second side of the second portion is bonded to or fused to the first side of the third portion.

11. The apparatus of claim 10, wherein:
at least one of the second side of the first portion and the first side of the second portion comprises a heating element channel, and
the heating element channel houses the one or more heating element segments.

12. The apparatus of claim 10, wherein:
at least one of the second side of the second portion and the first side of the third portion comprises a cooling passage channel, and
the cooling passage channel houses the one or more cooling passage segments.

13. The apparatus of claim 10, wherein the one or more cooling passage segments are tubular.

14. The apparatus of claim 10, wherein:
the second side of the first portion is brazed to the first side of the second portion, and
the second side of the second portion is brazed to the first side of the third portion.

15. The apparatus of claim 10, wherein the first portion, the second portion, and the third portion are all made of an aluminum alloy.

16. The apparatus of claim 1, wherein the one or more heating element segments have a D-shaped cross-section.

17. The apparatus of claim 16, wherein the one or more cooling passage segments have an annular cross-section.

18. The apparatus of claim 1, wherein the main body is made of an aluminum alloy.

19. The apparatus of claim 1, further comprising a temperature sensor, wherein the temperature sensor is coupled with the main body.

20. The apparatus of claim 19, further comprising:
a power supply;
a coolant reservoir having a temperature control system;
a coolant pump; and
a controller configured to:
control the temperature control system to cause a coolant stored in the coolant reservoir to be maintained within a first temperature range that is between 5° C. and 50° C. below a setpoint temperature;
control the coolant pump to cause the coolant to flow from the coolant reservoir and through the one or more cooling passage segments; and
cause the one or more heating element segments to receive power from the power supply until the temperature sensor indicates that a temperature of the pedestal is at or greater than the setpoint temperature.
